(19) United States
(12) Patent Application Publication
(10) Pub. No.: US 2006/0125002 A1
(43) Pub. Date: Jun. 15, 2006

(54) Semiconductor structure for operation at high current

(75) Inventor: Wen-Hsiung Wang, Taipei (TW)

Correspondence Address: TROXELL LAW OFFICE PLLC, SUITE 1404, 5205 LEESBURG PIKE, FALLS CHURCH, VA, 22041, US

(73) Assignee: Niko Semiconductor co., Ltd.

(21) Appl. No.: 11/008,941

(22) Filed: Dec. 13, 2004

(51) Int. Cl. H01L 29/76

(52) U.S. Cl. 257/341

(57) ABSTRACT

A semiconductor structure for operation at high current related to a small volume of semiconductor structure that could enhance the rated current of the prior art, especially used in high-power cells of integrated circuits like transistors in the power supply. The semiconductor structure uses the third metal layer for enhancing the rated current of the circuit of the prior through parallel connected the circuit of the prior.

### BACKGROUND OF THE INVENTION

1. Field of the Invention

The present invention relates to a semiconductor structure for operation at high current, and more particularly to a semiconductor structure used in a finger MOS transistor circuit for supplying more rated current in the constant volume of semiconductor.

2. Description of the Related Art

Logical circuit consists of multi-transistor element mostly, and the multi-transistor element discriminated a BJT (Bipolar Junction Transistor) and a FET (Field Effect Transistor) type. The BJT type comprises the RTL (resister-transistor), the DTL (diode-transistor logic), the TTL (transistor-transistor logic), the ECL (emitter-coupled logic), the CTL (complementary transistor logic). The FET type comprises the NMOS, the PMOS and the CMOS, and user could choose one kind of types to use.

Now those electronic cells were manufactured be an IC (integrated circuit), and the IC were be used publicly as a result of the small-volume, multi-function, convention, low consumption and high dependence. At above mentioned, the TTL and the CMOS are popular in application.

The prior MOS (metal-oxide semiconductor) used in speedy transmission circuit and the interface of output. Moreover the prior FET (Field Effect Transistor) has the advantage of low consumption and high-density fabrication. Using the prior MOS and the prior FET to operate in coordination flexibly for consisted an IC with high-speed, low consumption and high-density fabrication.

However it is important to develop a semiconductor cell with high current or high power in limited volume, more specially, the power stage in electronic device often operated in high current or raising voltage. Therefore the OEMs need to design the circuit to operate with the high-effect power transistor urgently.

FIG. 1 shows one of the traditional MOS IC design types. A quantum active 10 is based on p type or n type; or base on p-well or n-well, and a plurality of first metal layers 20 is situated in a vertical area of the quantum active 10. There is a plurality of source areas and drain areas situated in the first metal layers 20, and each of the first metal layers 20 vertical connects to the quantum active 10 through a plurality of contacts 30, and the contacts 30 should be the source terminal contacts or the drain terminal contacts.

Furthermore, MOS semiconductor uses a second metal layer 40 to cover the quantum active 10 for being electrically connected. However, a first vertical channel layer 50 connected to the second metal layer 40 and first metal layer 20 for passing an electronic current. Moreover a gate terminal 60 is situated between each of the source areas and drain areas. The prior art is limited at the IC circuit structure of the second metal layer 40 to pass the rated current . So it is difficult to develop IC circuit structure for operation at high current under the IC circuit structure of the prior.

In above mentioned we should insert a structure with small-volume and high current into the IC circuit structure of the prior for supplying the application of high power and high current. Therefore the present invention integrated the technic of parallel circuit with the layout of semiconductor.

### SUMMARY OF THE INVENTION

The object of the present invention is related to a semiconductor structure operation at high current, and manufactured with general semiconductor equipment. The present invention could improve the IC circuit structure of the prior for supplying the efficacy of the small-volume and high current.

For reaching above object, the present invention improved the IC circuit structure of the prior and integrated a third metal layer with the layout technic of semiconductor for supplying the semiconductor structure operation at high current.

The present invention comprises a plurality of drain areas, a plurality of source areas, a quantum active area, a plurality of gate areas, a second metal layer and a third metal layer.

Each of the drain areas has a plurality of drain terminals, and each of the source areas has a plurality of source terminals, and each of the gate areas situated between one of the drain areas and one of the source areas. Moreover the quantum active area has the capability of the quantum jumping. The second metal layer is situated above each of the drain areas or each of the source areas, and electrically connected to each one. The third metal layer is situated above the second metal layer, and electrically connected to each of the gate areas. Wherein a plurality of transistors is formed with each of the drain areas, each of the source areas and each of the gate areas, and each of the drain terminals and each of the source terminals connected to a conductive area for operation at high current.

### BRIEF DESCRIPTION OF THE DRAWINGS

The various objects and advantages of the present invention will be more readily understood from the following detailed description when read in conjunction with the appended drawing, in which:

FIG. 1 shows a perspective drawing of the integrated circuit structure with the transistor having two metal layers of the prior art; and

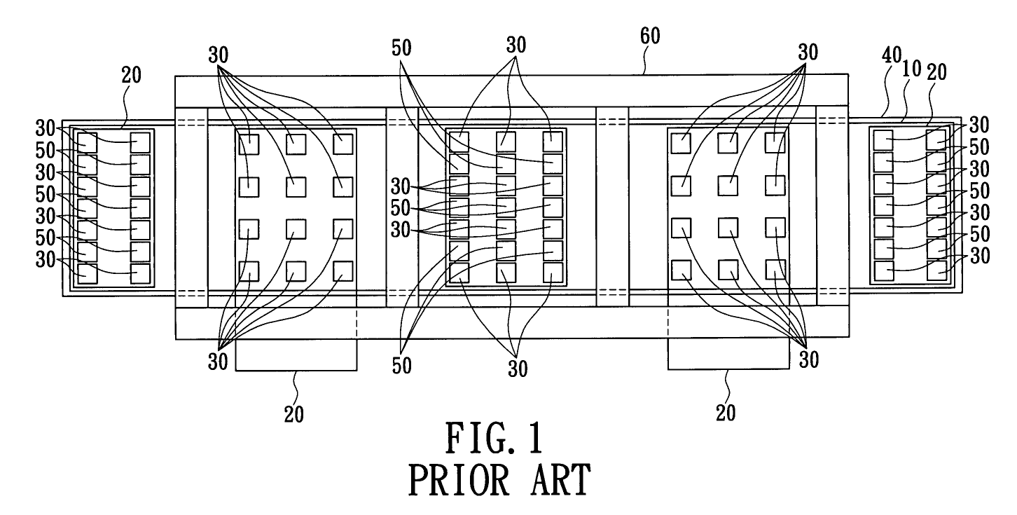

FIG. 2 shows a perspective drawing of the integrated circuit structure with the transistor having three metal layers of the present invention.

### DETAILED DESCRIPTION OF PREFERRED EMBODIMENTS

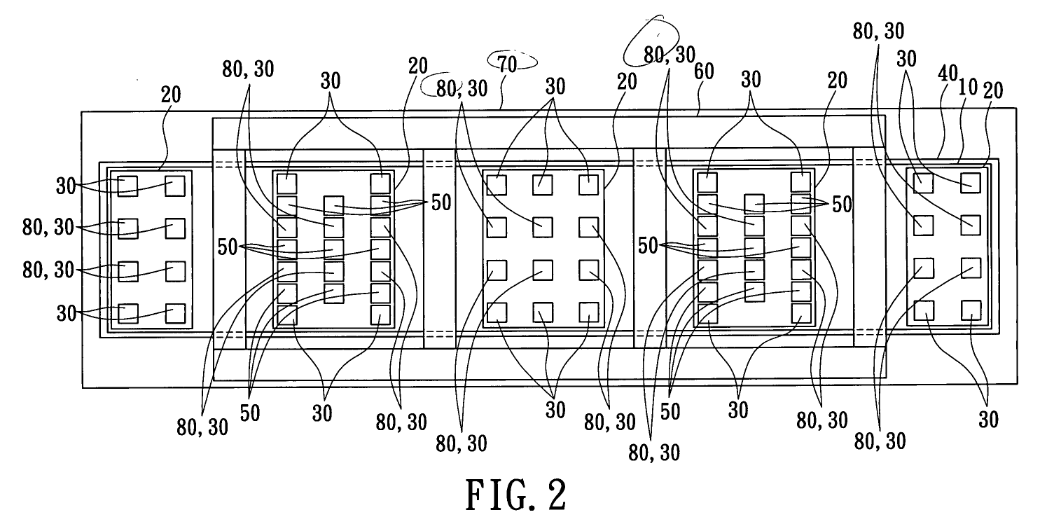

FIG. 2 shows the perspective drawing of the present invention. The present invention uses a third metal layer 70 for parallel connecting other cells to enhance the rated current. Furthermore the present invention was corrected partly for parallel connection conveniently at layout, more specially, parallel connected to the second metal layer 40 of the IC circuit structure of the prior. Moreover a quantum active 10 is based on p type or n type; or base on p-well or n-well, and a plurality of first metal layers 20 is situated in a vertical area of the quantum active 10. There is a plurality of source areas and drain areas situated in the first metal layers 20, and each of the first metal layers 20 vertical connects to the quantum active 10 through a plurality of contacts 30, and the contacts 30 should be the source terminal contacts or the drain terminal contacts.

Furthermore, MOS semiconductor uses a second metal layer 40 to cover the quantum active 10 for being electrically connected. However, a first vertical channel layer 50 connected to the second metal layer 40 and the first metal layer 20 for passing an electronic current. Moreover a gate terminal 60 is situated between each of the source areas and drain areas.

Furthermore the gate terminal 60 of the present invention was situated on the vertical purlieus of the third metal layer 70 for operation at high current. The present invention has a plurality of second vertical channel layers 80 that is the best different from the prior art. The second metal layer 40 electrically connects to the third metal layer 70 through the plurality of second vertical channel layers 80 for operation at high current. The third metal layer 70 and the second metal layer 40 were parallel connected through a circuit for enhancing the rated current of the circuit and increasing the capacity of followed current in each of the source areas and each of the drain areas. (The third metal layer 70 used to compensate the capacity of the circuit and be heat dissipation) (The gate terminal 60 solves the Coulomb Blockade).

The detail description of the present invention is that the present invention comprises a plurality of drain areas, a plurality of source areas, a quantum active area 10, a plurality of gate areas 60 (was situated middle the first metal layer area 20), a second metal layer 40 and a third metal layer 70. Moreover each of the drain areas has a plurality of drain terminals, and each of the source areas has a plurality of source terminals, and each of the gate areas 60 situated between one of the drain areas and one of the source areas. Moreover the quantum active area 10 has the capability of the quantum jumping. The second metal layer 40 is situated above each of the drain areas or each of the source areas, and electrically connected to each one. The third metal layer 70 is situated above the second metal layer 40, and electrically connected to each of the gate areas 60. Wherein a plurality of transistors is formed with each of the drain areas, each of the source areas and each of the gate areas 60, and each of the drain terminals and each of the source terminals connected to a conductive area for operation at high current.

The first metal layer 20 is situated at each of the drain areas or each of the source areas, and electrically connected to the quantum active area 10 by each of the drain terminals and each of the source terminals. Moreover each of the drain terminals parallel connects at least one of the second metal layer 40 or the third metal layer 70 for operation at high current. And each of the source terminals parallel connects at least one of the second metal layer 40 or the third metal layer 70 for operation at high current. The third Metal layer 70 parallel connected to the second Metal layer 40 for operation at high current, and the second Metal layer 40 connected to the first Metal layer 20 through a first vertical channel layer 50, and the second Metal layer 40 connected to the third Metal layer 70 through a second vertical channel layer 80.

The features of the present invention are following:

1. Providing a structure for operation at high current in equal volume.

2. Enhancing the capacity of the layout with the third metal layer.

3. Be manufactured from the present equipment.

4. Using at the structure with high current extensively.

5. Using at the advanced procedure.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A semiconductor structure for operation at high current, comprising:
a plurality of drain areas, wherein each of the drain areas has a plurality of drain terminals;
a plurality of source areas, wherein each of the source areas has a plurality of source terminals;
a quantum active area being capability of the quantum jumping;
a plurality of gate areas, wherein each of the gate areas is situated between one of the drain areas and one of the source areas;
a second metal layer situated on and electrically connected to one of the drain areas and the source areas;
a third metal layer is situated above the second metal layer, and electrically connected to each of the gate areas;
wherein a plurality of transistors is formed with each of the drain areas, each of the source areas and each of the gate areas, and each of the drain terminals and each of the source terminals connected to a conductive area for operation at high current.

2. The Semiconductor structure of claim 1, further comprising a first metal layer situated at each of the drain areas or each of the source areas, and electrically connected to the quantum active area by each of the drain terminals and each of the source terminals.

3. The semiconductor structure of claim 1, wherein each of the drain terminals parallel connects at least one of the second metal layer and the third metal layer for operation at high current.

4. The semiconductor structure of claim 1, wherein each of the source terminals parallel connects at least one of the second metal layer and the third metal layer for operation at high current.

5. The semiconductor structure of claim 1, wherein the third metal layer parallel is connected to the second metal layer for operation at high current.

6. The semiconductor structure of claim 1, wherein the second metal layer is connected to the first metal layer through a first vertical channel layer.

7. The semiconductor structure of claim 1, wherein the second metal layer is connected to the third Metal layer through a second vertical channel layer.
